(19) United States
(12) Patent Application Publication
(10) Pub. No.: US 2026/0039017 A1
(43) Pub. Date: Feb. 5, 2026

(54) BASE STATION ANTENNA

(71) Applicant: Outdoor Wireless Networks LLC, Claremont, NC (US)

(72) Inventors: Cheng XUE, Suzhou, Jiangsu (CN); Changfu CHEN, Suzhou, Jiangsu (CN); Jian ZHANG, Suzhou, Jiangsu (CN); Bin SUN, Suzhou, Jiangsu (CN); Xun ZHANG, Suzhou, Jiangsu (CN); Pengfei GUO, Suzhou, Jiangsu (CN)

(21) Appl. No.: 19/100,061

(22) PCT Filed: Sep. 1, 2023
(86) PCT No.: PCT/US2023/073265

§ 371 Date: Jan. 30, 2025

(30) Foreign Application Priority Data
Oct. 10, 2022 (CN) 202211232611.X

(51) Int. Cl. H01Q 5/335; H01Q 1/24; H01Q 1/48; H01Q 19/10

(52) U.S. Cl. CPC H01Q 5/335; H01Q 1/246; H01Q 1/48; H01Q 19/108

(57) ABSTRACT

The present disclosure relates to a base station antenna. comprising: a reflector: a first frequency band radiating element located on the front side of the reflector; and a feed board located on the front side of the reflector. the feed board being configured to feed the first frequency band radiating element, in which. a resonant circuit in a grounding path of the first frequency band radiating clement is formed on the feed board, and the resonant circuit is configured to at least suppress current within a second frequency band different from the first frequency band (FIG. 2a).

### RELATED APPLICATION

The present application claims priority from and the benefit of Chinese Patent Application No. 202211232611.X, Filed Oct. 10, 2022, the disclosure of which is hereby incorporated herein by reference in full.

### TECHNICAL FIELD

The present disclosure generally relates to the field of radio communications, and more specifically, to a base station antenna.

### BACKGROUND ART

Cellular communications systems are well known in the art. In a cellular communications system, a geographic area is divided into a series of regions that are referred to as “cells” which are served by respective base stations. The base station may include one or more base station antennas that are configured to provide two-way radio frequency (“RF”) communications with mobile subscribers that are within the cell served by the base station.

In many cases, each base station is divided into “sectors”. In perhaps the most common configuration, a small hexagonally shaped cell is divided into three 120° sectors, and each sector is served by one or more base station antennas that produce a radiation pattern or an “antenna beam” with an azimuth half power beam width (HPBW) of approximately 65°. Typically, the base station antennas are mounted on a tower structure, with the antenna beams that are generated by the base station antennas directed outwardly. Base station antennas are often realized as linear or planar phased arrays of radiating elements. multi-band antennas have been introduced, where a plurality of linear arrays of radiating elements are comprised in a single antenna. A very common multi-band antenna comprises a linear array of “low-band” radiating elements to provide service for some or all of the 617-960 MHZ frequency bands; a linear array of “mid-band” radiating elements to provide service for some or all of the 1,427-2,690 MHz frequency bands; and/or a linear array of “high-band” radiating elements to provide service for some or all of the 3.1-4.2 GHz frequency bands. These linear arrays of low-band radiating elements, mid-band radiating elements, and/or high-band radiating elements are typically mounted side-by-side.

However, in multi-band antennas, radiating elements in different frequency bands interfere with each other. For example, low-band radiating elements may produce relatively large scattering effects on the mid-band radiating elements and/or high-band radiating elements nearby, thereby affecting the performance, for example, the bean width and the like of the antenna beam generated by the mid-band radiating elements and/or high-band radiating elements.

Furthermore, mid-band radiating elements and/or high-band radiating elements may also cause undesirable interference to the low-band radiating elements. In some cases, low-band frequency radiation may be generated by excitation of low-band frequency currents on the corresponding mid-band radiating elements and/or high-band radiating elements, thereby interfering with the radiation performance of the low-band radiating elements in front of them. For example, low-band frequency currents formed or induced on the reflector may excite the respective mid-band radiating elements and/or high-band radiating elements. It is often necessary to provide decoupling circuits on feed stalk for mid-band radiating elements and/or high-band radiating elements to radiating elements and low-band radiating elements, for example, to suppress common-mode signals. However, in some application scenarios, only disposing a decoupling circuit on feed stalk for high-band radiating elements is insufficient to meet the requirements for decoupling performance, for example, common-mode signal suppression performance. Therefore, in order to meet the requirements for decoupling performance, it is often necessary to reduce the height of the mid-band radiating elements and/or the high-band radiating elements such that the mid-band radiating elements and/or high-band radiating elements are not easily excited by low-band frequency currents, but this in turn negatively affects the impedance matching performance of the mid-band radiating elements and/or high-band radiating elements, which may lead to poor radiation efficiency of the mid-band radiating elements and/or high-band radiating elements. This is undesirable.

### SUMMARY

Therefore, the objective of the present disclosure is to provide a base station antenna capable of overcoming at least one drawback in the prior art.

According to a first aspect of the present disclosure, a base station antenna is provided, which comprises: a reflector; a first frequency band radiating element located on the front side of the reflector; and a feed board located on the front side of the reflector, the feed board being configured to feed the first frequency band radiating element, in which, a resonant circuit in a grounding path of the first frequency band radiating element is formed on the feed board, and the resonant circuit is configured to at least suppress current within a second frequency band different from the first frequency band. ground connection of the first frequency band radiating element on the feed board to the reflector.

In some embodiments, the resonant circuit may comprise an LC resonant circuit.

In some embodiments, the LC resonant circuit may be configured as an LC parallel resonant circuit.

In some embodiments, a first grounding area may be provided on the front surface of a dielectric substrate of the feed board, where a grounding conductive area of the first frequency band radiating element is electrically connected to the first grounding area; and a second grounding area may be provided on the rear surface of the dielectric substrate of the feed board, where the second grounding area is coupled to the reflector, in which, the first grounding area and the second grounding area form a first capacitance in an LC parallel resonant circuit.

In some embodiments, the second grounding area may be provided with a window at least partially exposing the rear surface of the dielectric substrate.

In some embodiments, there may be no metal coating present within the window.

In some embodiments, the capacitance value of the first capacitance is capable of being adjusted by changing the position of the window relative to the first grounding area, the size and/or the shape of the window, or by adding additional windows.

In some embodiments, the window may overlap at least a portion of the first grounding area.

In some embodiments, a first projection of the first grounding area on the dielectric substrate may be located within a second projection of the window on the dielectric substrate. than the area of the first grounding area.

In some embodiments, the resonant circuit may be provided with a first meandered trace on the front surface of the dielectric substrate, and the first meandered trace forms a first inductance in the LC parallel resonant circuit.

In some embodiments, a first end of the first meandered trace may be electrically connected to the first grounding area, and a second end of the first meandered trace may be electrically connected to the second grounding area.

In some embodiments, the second end of the first meandered trace may be electrically connected to the second grounding area via a first conductive structure that passes through the dielectric substrate.

In some embodiments, the first conductive structure may comprise a metalized via or conductive pin.

In some embodiments, the first grounding area may have a polygonal shape.

In some embodiments, the polygonal shape may be quadrilateral, hexagonal, nonagonal, or dodecagonal.

In some embodiments, one or more first meandered traces may be connected on one or all sides of the polygon, respectively.

In some embodiments, the LC parallel resonant circuit may be configured to allow current within the first frequency band to pass through and prevent current within the second frequency band from passing through.

In some embodiments, the LC parallel resonant circuit may be configured as a band-stop filter circuit.

In some embodiments, the shape of the first meandered trace may be a pulse width modulation waveform, an inverse S-shape, a serrated

In some embodiments, the feed board may have one or more slots that pass through the first grounding area and dielectric substrate, where a feed stalk of the first frequency band radiating element passes through the front side of the feed board and extends through at least one of the slots to the rear side of the feed board.

In some embodiments, the grounding conductive area of the first frequency band radiating element may be electrically connected to the first grounding area on the front side of the feed board.

In some embodiments, the grounding conductive area of the first frequency band radiating element may pass through the one or more slots and be electrically connected to the outer conductor of the coaxial transmission line for feeding the first frequency band radiating element on the rear side of the feed board.

In some embodiments, the grounding conductive area of the first frequency band radiating element may be electrically connected to the first grounding area via a second conductive structure that passes through the dielectric substrate.

In some embodiments, the second conductive structure may comprise a metalized via or conductive pin.

In some embodiments, a feed trace of the first frequency band radiating element may pass through the one or more slots and being electrically connected to the inner conductor of the coaxial transmission line for feeding the first frequency band radiating element on the rear side of the feed board.

In some embodiments, the feed trace of the first frequency band radiating element and the inner conductor of the coaxial transmission line may be welded to each other on the feed stalk of the first frequency band radiating element. direction perpendicular to the feed board to be located in the window region.

In some embodiments, the LC resonant circuit may be configured as an LC parallel resonant circuit.

In some embodiments, the first grounding area may be provided on the front surface of the dielectric substrate of the feed board, where the grounding conductive area of the first frequency band radiating element is electrically connected to the first grounding area; and the second grounding area may be provided on the rear surface of the dielectric substrate of the feed board, where the second grounding area is coupled to the reflector in a grounding manner.

In some embodiments, the second grounding area may be provided with a window that partially exposes the rear surface of the dielectric substrate.

In some embodiments, a metal pattern may be printed within the window, the metal pattern comprising a first conductor strip and a second meandered trace.

In some embodiments, the first conductor strip may be provided as a second capacitance in the LC series resonant circuit formed with the first grounding area.

In some embodiments, the second meandered trace may form a second inductance in the LC series resonant circuit.

In some embodiments, a first end of the second meandered trace may be electrically connected to the first conductor strip, and a second end of the second meandered trace may be electrically connected to the second grounding area.

In some embodiments, the LC series resonant circuit may be configured to allow current within the first frequency band to pass through through.

In some embodiments, the LC series resonant circuit may be configured as a band-pass filter circuit.

In some embodiments, the first conductor strip may be a conductor strip in homocentric squares, an annular conductor strip or a bar conductor strip.

In some embodiments, the feed board may have a one or more slots that pass through the first grounding area and dielectric substrate, where a feed stalk of the first frequency band radiating element passes through the front side of the feed board and extends through the one or more slots to the rear side of the feed board.

In some embodiments, the grounding conductive area of the first frequency band radiating element may be welded to the first grounding area on the front side of the feed board.

In some embodiments, the grounding conductive area of the first frequency band radiating element may pass through the one or more slots and be electrically connected to the outer conductor of the coaxial transmission line for feeding the first frequency band radiating element on the rear side of the feed board.

In some embodiments, the grounding conductive area of the first frequency band radiating element may be electrically connected to the first grounding area via a second conductive structure that passes through the dielectric substrate.

In some embodiments, the second conductive structure may comprise a metalized via or conductive pin.

In some embodiments, a feed trace of the first frequency band radiating element may pass through the one or more slots and be electrically connected to the inner conductor of the coaxial transmission line for feeding

In some embodiments, the feed trace of the first frequency band radiating element and the inner conductor of the coaxial transmission line may be welded to each other on the feed stalk of the first frequency band radiating element.

In some embodiments, the resonant circuit may comprise a capacitive circuit.

In some embodiments, a first grounding area may be provided on the front surface of the dielectric substrate of the feed board, where a grounding conductive area of the first frequency band radiating element is electrically connected to the first grounding area; and a second grounding area may be provided on the rear surface of the dielectric substrate of the feed board, where the second grounding area is coupled to the reflector in a grounding manner, in which, the first grounding area and the second grounding area form a third capacitance in the capacitive circuit.

In some embodiments, the second grounding area may be provided with a window at least partially exposing the rear surface of the dielectric substrate.

In some embodiments, there may be no metal coating present within the window.

In some embodiments, the window may overlap at least a portion of the first grounding area.

In some embodiments, a second projection of the window on the dielectric substrate may be located within a first projection of the first grounding area on the dielectric substrate.

In some embodiments, the area of the window may be smaller than the area of the first grounding area.

In some embodiments, the capacitive circuit may be configured to allow current within the first frequency band to pass through and prevent

In some embodiments, the capacitive circuit may be configured as a high-pass filter circuit.

In some embodiments, the feed board may have a one or more slots that pass through the first grounding area and dielectric substrate, where a feed stalk of the first frequency band radiating element passes through the front side of the feed board and extends through the one or more slots to the rear side of the feed board.

In some embodiments, the grounding conductive area of the first frequency band radiating element may be electrically connected to the first grounding area on the front side of the feed board.

In some embodiments, the grounding conductive area of the first frequency band radiating element may pass through the one or more slots and be electrically connected to the outer conductor of the coaxial transmission line for feeding the first frequency band radiating element on the rear side of the feed board.

In some embodiments, a feed trace of the first frequency band radiating element may pass through the one or more slots and be electrically connected to the inner conductor of the coaxial transmission line for feeding the first frequency band radiating element on the rear side of the feed board.

In some embodiments, the minimum distance between a radiating arm of the first frequency band radiating element and the reflector in a direction perpendicular to the reflector may be in the range of 0.2 to 0.3 wavelength, and the wavelength is the wavelength corresponding to the center frequency of the first frequency band.

### BRIEF DESCRIPTION OF THE ATTACHED DRAWINGS

The present disclosure will be explained in greater detail by means of specific embodiments with reference to the attached drawings.

FIG. 1a is a schematic front view of a base station antenna according to some embodiments of the present disclosure, where the radome is removed, in which, two first frequency band radiating element arrays and two second frequency band radiating element arrays are exemplarily shown;

FIG. 1b is an end view of the base station antenna in FIG. 1a;

FIG. 2a is a schematic simplified perspective view of a base station antenna assembly formed by a first frequency band radiating element and a feed board for the first frequency band radiating element according to some embodiments of the present disclosure;

FIG. 2b is a side view of the assembly in FIG. 2a;

FIG. 3a is a frontal schematic diagram of a first feed stalk printed circuit board of a feed stalk of the first frequency band radiating element in FIG. 2a, where a first feed trace is printed on the front of the first feed stalk printed circuit board;

FIG. 3b is a frontal schematic diagram of a second feed stalk printed circuit board of a feed stalk of the first frequency band radiating element in FIG. 2a, where a second feed trace is printed on the front of the second feed stalk printed circuit board;

FIG. 4a is a schematic perspective view of the front side of the feed board in FIG. 2a;

FIG. 4b is a schematic plan view of the front side of the feed board in FIG. 4a;

FIG. 5a is a schematic perspective view of the rear side of the feed board in FIG. 2a, in which, the feed stalk of the first frequency band radiating element passes through a first slot in the feed board and is welded to a coaxial transmission line for feeding the first frequency band radiating element on the rear side of the feed board; in FIG. 5a, in which the feed stalk and coaxial transmission line are removed;

FIGS. 6a to 6c are schematic plan views of the front side of a feed board of a base station antenna according to embodiments of the present disclosure, respectively;

FIGS. 7a and 7b are schematic plan views of the front and rear sides of a feed board of a base station antenna according to further embodiments of the present disclosure;

FIGS. 8a and 8b are schematic plan views of the front and rear sides of a feed board of a base station antenna according to yet additional embodiments of the present disclosure;

FIG. 8c is a schematic perspective view of the feed board in FIG. 8a.

### DETAILED DESCRIPTION OF SPECIFIC EMBODIMENTS

The present disclosure will be described below with reference to the attached drawings, wherein the attached drawings illustrate certain embodiments of the present disclosure. However, it should be understood that the present disclosure may be presented in many different ways and is not limited to the embodiments described below; in fact, the embodiments described below are intended to make the disclosure of the present disclosure more complete and to fully explain the protection scope of the present disclosure to those of ordinary skill in the art. It should also be understood that the embodiments disclosed in the present disclosure may be combined in various ways so as to provide more additional embodiments.

It should be understood that the terms used herein are only used to describe specific embodiments, and are not intended to limit the scope of the present disclosure. All terms used herein (including technical terms and art unless otherwise defined. For brevity and/or clarity, well-known functions or structures may not be further described in detail.

As used herein, spatial relationship terms such as “upper,” “lower,” “left,” “right,” “front,” “back,” “high,” and “low” can explain the relationship between one feature and another in the attached drawings. It should be understood that, in addition to the orientations shown in the attached drawings, the terms expressing spatial relations also comprise different orientations of a device in use or operation. For example, when a device in the attached drawings rotates reversely, the features originally described as being “below” other features now can be described as being “above” the other features “. The device may also be oriented by other means (rotated by 90 degrees or at other locations), and at this time, a relative spatial relation will be explained accordingly.

As used herein, the term “A or B” comprises “A and B” and “A or B”, not exclusively “A” or “B”, unless otherwise specified.

As used herein, the term “schematic” or “exemplary” means “serving as an example, instance or explanation”, not as a “model” to be accurately copied “. Any realization method described exemplarily herein may not be necessarily interpreted as being preferable or advantageous over other realization methods. Furthermore, the present disclosure is not limited by any expressed or implied theory given in the above technical field, background art, summary of the invention or embodiments.

As used herein, the word “basically” means including any minor changes caused by design or manufacturing defects, device or component tolerances, environmental influences, and/or other factors.

As used herein, the term “partially” may be a part of any proportion. For example, it may be greater than 10%, 20%, 30%, 40%, 50%, 60%, 70%, 80%, 90%, or may even be 100%, i.e. all. similar terms may also be used herein, and thus are not intended to be limitative. For example, unless the context clearly indicates, the words “first”, “second” and other such numerical words involving structures or elements do not imply a sequence or order.

The present disclosure proposes a new base station antenna 100, which comprises: a reflector 113; a first frequency band radiating element 121 located on the front side of the reflector 113; and a feed board 141 located on the front side of the reflector 113, the feed board 141 being configured to feed the first frequency band radiating element 121, in which, a resonant circuit 200 in a grounding path of the first frequency band radiating element 121 is formed on the feed board 141, and the resonant circuit 200 is configured to at least suppress current within a second frequency band different from the first frequency band.

According to the technical solution of the base station antenna 100 of the present disclosure, a resonant circuit 200 in the grounding path of the first frequency band radiating element 121 is formed on the feed board 141, and the resonant circuit 200 may be configured as or be equivalent to an LC resonant circuit. In some embodiments, the LC resonant circuit may be configured as an LC parallel resonant circuit. In some embodiments, the LC resonant circuit may be configured as an LC series resonant circuit. In some embodiments, the resonant circuit 200 may be configured as a capacitive circuit. It should be understood that the resonant circuit 200 may also have other forms of parasitic capacitance and/or parasitic inductance, but are negligible because they are numerically small.

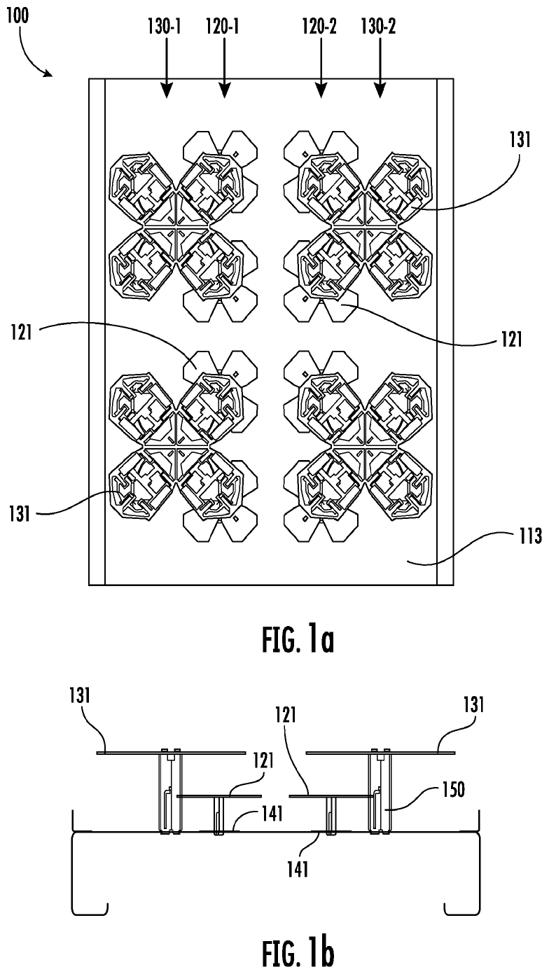

According to the technical solution of the base station antenna 100 of the present disclosure, the resonant circuit 200 for at least suppressing current within a second frequency band different from the first frequency band is disposed on the feed board 141 for the first frequency grounding path of the first frequency band radiating element 121 on the feed board 141. Compared with the resonant circuit or decoupling circuit conventionally disposed on the feed stalk 150 of the first frequency band radiating element 121, the resonant circuit 200 disposed on the feed board 141 according to the present disclosure is disposed closer to the reflector 113, such that it has better decoupling performance, for example, common-mode signal suppression performance. Furthermore, the height h (“height h” may be understood as the height of the feed stalk) of the first frequency band radiating element 121 in a direction perpendicular to the reflector 113 no longer needs to be shortened to realize decoupling, thereby improving the impedance matching performance and radiation efficiency of the first frequency band radiating element 121. This will be set forth in more detail below by means of FIGS. 1a to 8c. The same reference numerals are used in FIGS. 1a to 8c for the same components for ease of understanding.

FIG. 1a shows a schematic front view of a base station antenna 100 according to some embodiments of the present disclosure, where the radome is removed, in which, for example, the base station antenna 100 may have two first frequency band radiating element 121 arrays 120-1, 120-2 and two second frequency band radiating element 131 arrays 130-1, 130-2. FIG. 1b shows an end view of the base station antenna 100 in FIG. 1a.

As shown in FIG. 1a and FIG. 1b, a plurality of radiating elements 121 and 131 are mounted on the front side of the reflector 113 of the base station antenna 100. Each radiating element 121 and 131 is mounted to extend forwardly from the front surface of the reflector 113. The reflector 113 may serve as the ground plane structure of the radiating elements 121 and 131. The radiating elements 121 and 131 may comprise a first frequency band radiating element 121 (exemplarily a high-band 131 (exemplarily a low-band radiating element herein), and the second frequency band radiating element 131 extends further forward than the first frequency band radiating element 121. The frequency bands covered by the first frequency band radiating element 121 may be, for example, 3 GHz to 5 GHz or one or more partial ranges thereof. The frequency bands covered by the second frequency band radiating element 131 may be, for example, 617 MHz to 960 MHz or one or more partial ranges thereof. Here, it should be understood that the radiating elements 121 and 131 may also be mid-band radiating elements (the frequency bands covered may be, for example, 1,427 MHz to 2,690 MHz or one or more partial ranges thereof) or wide-band radiating elements.

In the embodiment of FIG. 1, the first frequency band radiating elements 121 are mounted in two columns to form two linear arrays 120-1-120-2 of first frequency band radiating elements 121. The second frequency band radiating elements 131 are mounted in two columns to form two linear arrays 130-1-130-2 of second frequency band radiating elements 131. It should be noted that similar elements may be individually referred to by their complete drawing reference numerals (for example, linear array 130-1) or collectively referred to by the first part of their drawing reference numerals (for example, linear array 130) herein.

In other embodiments not shown, the number of first frequency band radiating elements 121 and/or second frequency band radiating elements 131 and their linear arrays 120 and 130 may be different from the number shown in FIG. 1a. The linear arrays 120 and 130 may be arranged in any suitable inter-positional relationship, and may or may not extend the entire length of the base station antenna 100. The present disclosure is described below by taking the first frequency band radiating element 121 as an example. However, it should be understood that the technical content element 131 and/or radiating elements of other frequency band types within the scope understood by those skilled in the art.

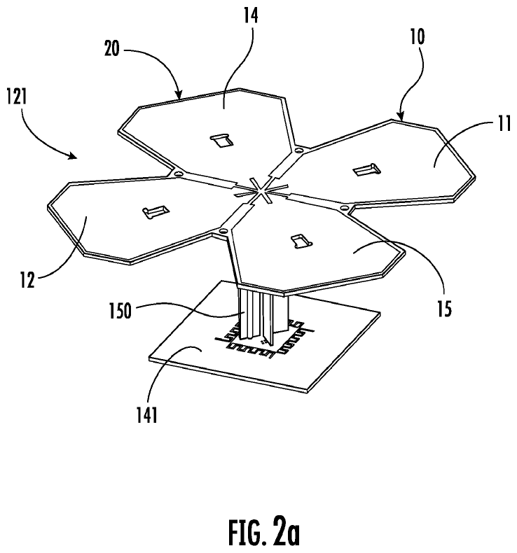

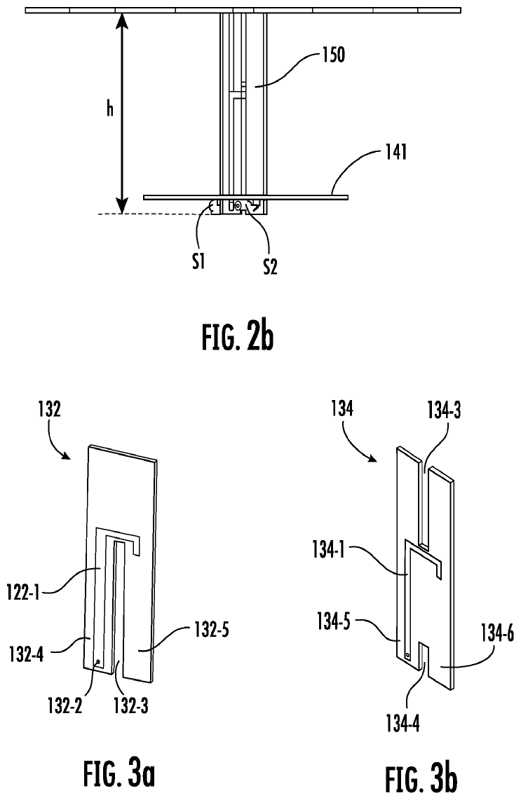

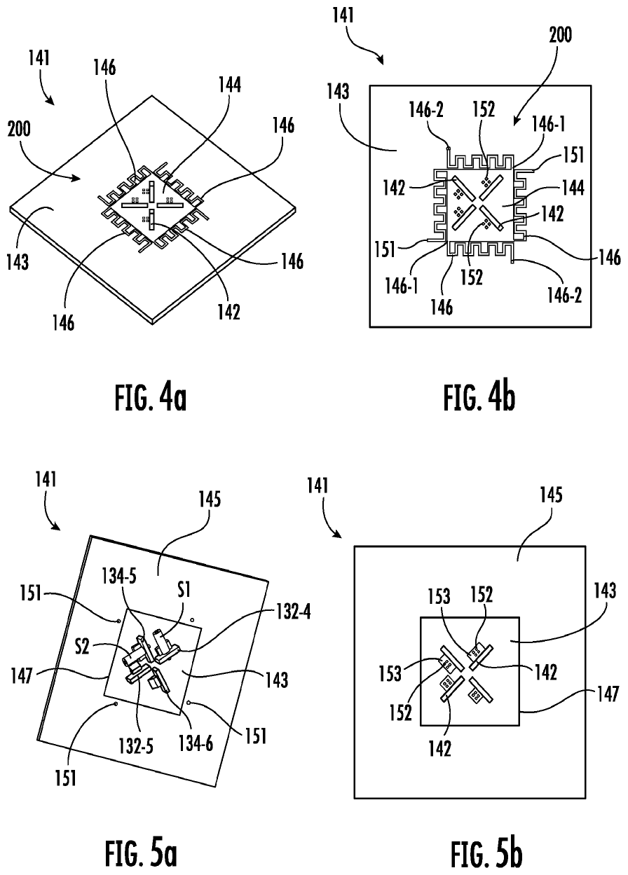

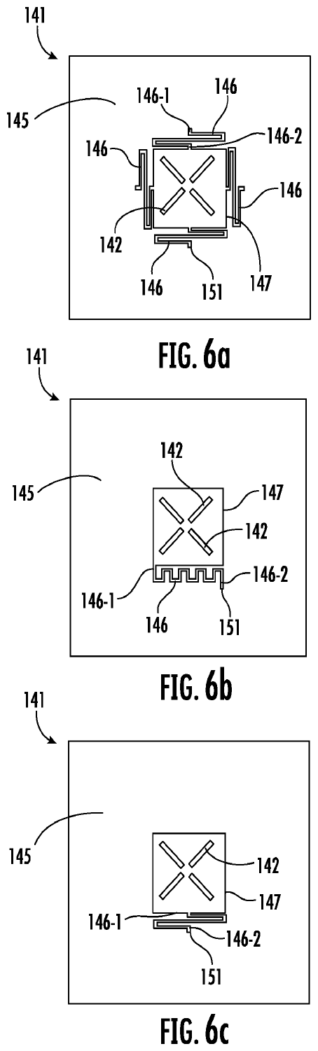

FIG. 2a shows a perspective view of a base station antenna 100 assembly formed by a first frequency band radiating element 121 and a feed board 141 for the first frequency band radiating element 121 according to some embodiments of the present disclosure. FIG. 2b shows a side view of the assembly in FIG. 2a. FIG. 3a shows a frontal schematic diagram of a first feed stalk printed circuit board 132 of a feed stalk 150 of the first frequency band radiating element 121 in FIG. 2a, where a first feed trace 132-1 is printed on the front of the first feed stalk printed circuit board 132. FIG. 3b shows a frontal schematic diagram of a second feed stalk printed circuit board 134 of a feed stalk 150 of the first frequency band radiating element 121 in FIG. 2a, where a second feed trace 134-1 is printed on the front of the second feed stalk printed circuit board 134. FIG. 4a shows a schematic perspective view of the front side of the feed board 141 in FIG. 2a; FIG. 4b shows a schematic plan view of the front side of the feed board 141 in FIG. 4a. FIG. 5a shows a schematic perspective view of the rear side of the feed board 141 in FIG. 2a, in which, the feed stalk 150 of the first frequency band radiating element 121 passes through a first slot 142 on the feed board 141 and is welded to a coaxial transmission line for feeding the first frequency band radiating element 121 on the rear side of the feed board 141. FIG. 5b shows a schematic plan view of the rear side of the feed board 141 in FIG. 5a, in which, the feed stalk 150 and the coaxial transmission lines S1-S2 are removed. FIGS. 6a to 6c show schematic plan views of the front side of a feed board 141 of a base station antenna 100 according to each embodiment of the present disclosure, respectively.

As shown in FIGS. 2a and 2b, the first frequency band radiating element 121 may be a cross-dipole radiating element that comprises a first feed stalk 150. The first radiator 10 may comprise a radiating arm 11 and a radiating arm 12, and may be configured to transmit and receive radio frequency signals in a first polarization direction, for example, +45° polarization direction. The second radiator 20 may comprise a radiating arm 14 and a radiating arm 15, and may be configured to transmit and receive radio frequency signals in a second polarization direction, for example, a −45° polarization direction. The feed stalk 150 may comprise a first feed stalk printed circuit board 132 for feeding the first radiator 10 and for grounding the first radiator 10, and may comprise a second feed stalk printed circuit board 134 for feeding the second radiator 20 and for grounding the second radiator 20. Furthermore, the height h of the first frequency band radiating element 121 in a direction perpendicular to the reflector 113 may be in the range of 0.1 to 0.4, or 0.2 to 0.3, for example, 0.21, 0.23, 0.25, 0.27, 0.29 wavelength, and the wavelength is the wavelength corresponding to the center frequency of the first frequency band. The feed stalk 150 may pass through the front side of the feed board 141 and extends through the feed board 141 to the rear side of the feed board 141, and may be electrically connected to the coaxial transmission lines S1-S2 for feeding the first frequency band radiating element 121 on the rear side of the feed board 141.

The specific structure of the first feed stalk printed circuit board 132 and the second feed stalk printed circuit board 134 of the feed stalk 150 is shown in FIGS. 3a and 3b, respectively. The first feed trace 132-1 for feeding the first radiator 10 may be printed on the first side of the first feed stalk printed circuit board 132, that is, the reader-facing side in FIG. 3a. A first grounding conductive area or grounding conductor for grounding the first radiator 10 that is not shown may be printed on the second side of the first feed stalk printed circuit board 132, that is, the side facing away from radiator 20 may be printed on the first side of the second feed stalk printed circuit board 134, that is, the reader-facing side in FIG. 3b. A second grounding conductive area or grounding conductor for grounding the second radiator 20 that is not shown may be printed on the second side of the second feed stalk printed circuit board 134, that is, the side facing away from the reader in FIG. 3b. Furthermore, the first feed stalk printed circuit board 132 may be disposed with a first slot 132-3 and two legs 132-4 and 132-5 located on both sides of the first slot 132-3, and the second feed stalk printed circuit board 134 may be disposed with a second slot 134-3, a third slot 134-4, and two legs 134-5 and 134-6 located on both sides of the third slot 134-4. The first slot 132-3 and the second slot 134-3 may match with each other such that the first feed stalk printed circuit board 132 and the second feed stalk printed circuit board 134 are capable of being embedded into each other, thereby forming a feed stalk 150 with a cross-shaped cross-section shown in FIG. 2a. The third slot 134-4 is configured to match the feed board 141, so as to define the length of the feed stalk 150 extending beyond the rear surface of the feed board 141.

The specific structure of the feed board 141 in FIG. 2a is shown in FIGS. 4a to 5b. A resonant circuit 200 may be formed on the feed board 141. The resonant circuit 200 may be configured as an LC parallel resonant circuit, for example, a band-stop filter circuit, to allow current within the first frequency band to pass through and prevent current within the second frequency band from passing through.

Referring to FIGS. 4a and 4b, the feed board 141 comprises a dielectric substrate 143. A first grounding area 144 is further provided on the front surface of the dielectric substrate 143, and the grounding conductive area of the first frequency band radiating element 121 is electrically connected to the first grounding area 144. In some embodiments, 121 may be directly welded to the first grounding area 144. In some embodiments, the grounding conductive area of the first frequency band radiating element 121 may be welded to the ground pad on the back side of the feed board and electrically connected to the first grounding area 144 via a conductive structure, for example, a metalized via.

Referring to FIGS. 5a and 5b, a second grounding area 145 is provided on the rear surface of the dielectric substrate 143, and the second grounding area 145 may be coupled to the reflector 113 in a grounding manner, while the reflector 113 may be considered as a common ground of the base station antenna. The first grounding area 144 and the second grounding area 145 may each be configured as a respective metal coating area, for example, a copper-clad area, and may form a capacitance in the LC parallel resonant circuit (hereinafter referred to as a first capacitance for differentiation purposes), in which, the first grounding area 144 and the second grounding area 145 may be equivalent to two electrode plates of the first capacitance. Furthermore, at least one (exemplarily four herein) first meandered trace 146 is provided on the front surface of the dielectric substrate 143, and the first meandered trace 146 may form an inductance in the LC parallel resonant circuit 200 (hereinafter referred to as the first inductance for differentiation purposes). In this way, the LC parallel resonant circuit 200 may be formed as a ground connection, for example, a grounding welding portion, extending from the first frequency band radiating element 121 on the feed board 141 to the reflector 113.

The first grounding area 144 may have a polygonal shape. In the embodiment of FIG. 4b, the first grounding area 144 is exemplarily quadrilateral, for example, rectangular in shape. However, it should be understood that the polygonal shape may also be hexagonal, nonagonal, dodecagonal or other shapes. The first meandered trace 146 may be embodiments, the first grounding area 144 may also be configured as a circle, oval, or an arc in at least some sections. In other embodiments, the first grounding area 144 may also be configured as an irregular shape. A first meandered trace 146 may be connected on at least one side edge of the first grounding area, respectively.

As shown in FIG. 5b, a window 147 may be provided in the second grounding area 145 that at least partially exposes the rear surface of the dielectric substrate 143. That is, there may be no metal coating, for example, a copper-clad layer, within the window 147. It can be seen from comparing FIGS. 4b and 5b that the window 147 may have the same or similar shape as the first grounding area 144. In some embodiments, the area of the window 147 may be greater than the area of the first grounding area 144, and the window 147 may overlap at least a portion of the first grounding area 144. In some embodiments, a first projection of the first grounding area 144 on the dielectric substrate 143 may be located within a second projection of the window 147 on the dielectric substrate 143. The resonance characteristics of the LC parallel resonant circuit, for example, the capacitance value of the first capacitance, is capable of being adjusted by changing the number of windows 147 that are provided, the position relative to the first grounding area 144, the size of the window, and/or the shape of the window 147. As such, current in the second frequency band is capable of being suppressed in a targeted manner.

Continuing to refer to FIGS. 4b and 5a, the first end 146-1 of the respective first meandered trace 146 may be electrically connected, for example, directly integrally formed, with the first grounding area 144. The second end 146-2 of the first meandered trace 146 may be electrically connected to the second grounding area 145. For example, the second end 146-2 of the first meandered trace 146 may be electrically connected to the through the dielectric substrate 143. The first conductive structure 151 may comprise a metalized via or conductive pin. As such, the first meandered trace 146 may be bridged between the first grounding area 144 and the second grounding area 145, and thus form an LC parallel resonant circuit with the first capacitance.

In the embodiment of FIG. 4b, a first meandered trace 146 is connected to all edges of the polygon, respectively, and the first meandered trace 146 is shaped as a PWM waveform. However, it should be understood that the number of the first meandered trace 146, the position relative to the first grounding area 144, the size, and/or shape may be changed to adjust the inductance value of the first inductance in the LC parallel resonant circuit 200. As such, current in the second frequency band is capable of being suppressed in a targeted manner.

As shown in FIG. 6a, the first meandered trace 146 may be configured as an inverse S-shape. Here, it should be understood that the first meandered trace 146 may also be configured as a serrated waveform, a sinusoidal waveform, or other shape. In the embodiment of FIG. 6b, one first meandered trace 146 having pulse width modulation (PWM) waveform is connected to a portion of edges (exemplarily only one edge herein) of the polygonal first grounding area 144. It should be understood that as the number of first meandered traces 146 in parallel increases, the smaller the equivalent series inductance value in the LC parallel resonant circuit.

In the embodiments of FIGS. 6b and 6c, one first meandered trace 146 having an inverse S-shape is connected to a portion of edges (exemplarily only one edge herein) of the polygonal first grounding area 144. Where the length of the first meandered trace 146 is the same, the first meandered trace 146 having an inverse S-shape with a lower degree of bending may have a smaller inductance value than the first meandered trace

The feed board 141 may also be configured with a first slot 142 that passes through the first grounding area 144 and dielectric substrate 143, and the feed stalk 150 of the first frequency band radiating element 121 may extend from the front side of the feed board 141 through the first slot 142 to the rear side of the feed board 141. As shown in FIG. 5b, the first slot 142 may be observed in a direction perpendicular to the feed board 141 to be located in the region of the window 147, and may be configured to be suitable for the arrangement structure for the legs 132-4 and 132-5 of the first feed stalk printed circuit board 132 and the legs 134-5 and 134-6 of the second feed stalk printed circuit board 134 of the feed stalk 150 to pass through. Here, four first slots 142 are provided that are distributed in the shape of a cross, such that the two legs 132-4-132-5 of the first feed stalk printed circuit board panel 132 and the two legs 134-5-134-6 of the second feed stalk printed circuit board 134 are capable of extending to the rear side of the feed board 141 through the corresponding slots. As such, as shown in FIG. 4a, the first feed trace 132-1 on the first feed stalk printed circuit board 132 of the feed stalk 150 may be electrically connected, for example, welded, to the inner conductor of the first coaxial transmission line S1 for feeding the first radiator 10 of the first frequency band radiating element 121 on the rear side of the feed board 141, and the first grounding conductive area on the first feed stalk printed circuit board 132 may be electrically connected, for example, welded, to the outer conductor of the first coaxial transmission line S1 on the rear side of the feed board 141.

In order to facilitate the electrical connection of the first feed stalk printed circuit board 132 with the first coaxial transmission line S1, a through hole 132-2 (refer to FIG. 3a) may also be disposed on the first feed stalk printed circuit board 132, for example, on the free end of the leg 132-4, for the inner conductor of the first coaxial transmission line S1 to pass S1 may be electrically connected to the first grounding conductive area on the second side of the first feed stalk printed circuit board 132, and the inner conductor of the first coaxial transmission line S1 may be electrically connected to the first feed trace 132-1 on the first side of the first feed stalk printed circuit board 132 by passing through the through hole 132-2 on the second side of the first feed stalk printed circuit board 132.

Furthermore, as shown in FIGS. 4b and 5b, in order to facilitate the electrical connection of the first grounding conductive area with the first grounding area 144, the feed board 141 may also be configured with: a second conductive structure 152 passing through the first grounding area 144 and dielectric substrate 143; and a ground pad 153 disposed on the rear surface of the dielectric substrate 143 surrounding the second conductive structure 152. As such, the first grounding conductive area and the outer conductor of the first coaxial transmission line S1 may be welded to each other at the ground pad 153 on the back side of the feed board 141, and be electrically connected to the first grounding area 144 on the front side of the feed board 141 through the second conductive structure 152. In some embodiments not shown, the first grounding conductive area of the first frequency band radiating element 121 may also be electrically connected, for example, directly welded, to the first grounding area 144 on the front side of the feed board 141. Furthermore, as shown in FIGS. 4a to 5b, the arrangement embodiment of the second feed stalk printed circuit board 134 and the second coaxial transmission line S2 may be similar to the arrangement embodiment of the first feed stalk printed circuit board 132 and the first coaxial transmission line S1. Hence, it will not be repeated here.

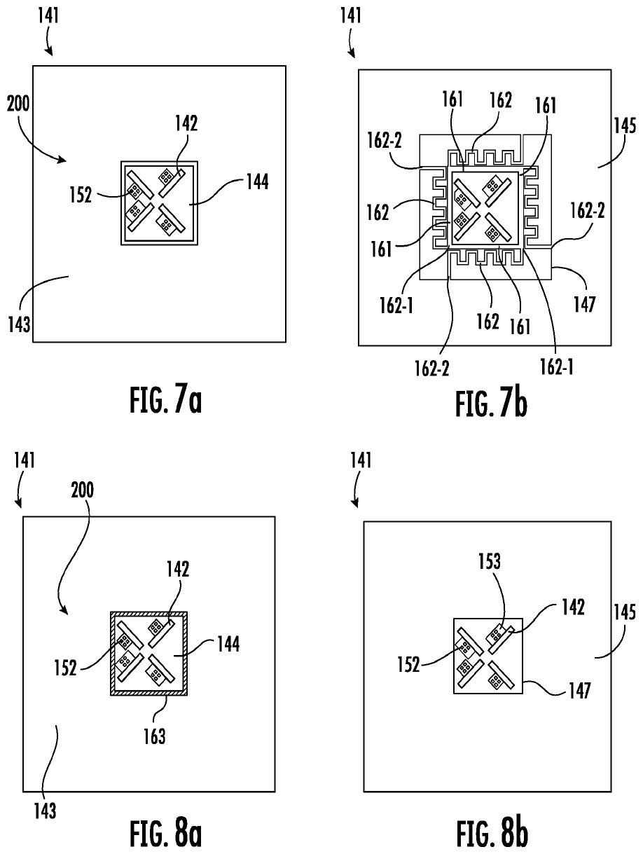

FIGS. 7a and 7b show schematic plan views of the front side and the rear side of a feed board 141 of a base station antenna 100 according to embodiments of FIGS. 7a and 7b, the resonant circuit 200 is configured as an LC series resonant circuit, to allow current within the first frequency band to pass through and prevent current within the second frequency band from passing through. In some embodiments, the LC series resonant circuit may be configured as a band-pass filter circuit. It should be understood that the LC series resonant circuit may also be configured as high-pass filter circuit or band-stop filter circuit.

Referring to FIGS. 7a and 7b, a base station antenna according to additional embodiments of the present disclosure is further described. It should be understood that the foregoing description may be applied to the following embodiments as long as it does not contradict each other, unless otherwise stated. As shown in FIGS. 7a and 7b, a first grounding area 144 may be provided on the front surface of the dielectric substrate 143 of the feed board 141, and the grounding conductive area of the first frequency band radiating element 121 is electrically connected to the first grounding area 144. A second grounding area 145 may be provided on the rear surface of the dielectric substrate 143 of the feed board 141, and the second grounding area 145 is coupled to the reflector 113 in a grounding manner. The second grounding area 145 may be provided with a window 147 partially exposing the rear surface of the dielectric substrate 143.

A metal pattern may be printed within the window 147, the metal pattern comprising a first conductor strip 161 and a meandered trace 162 (hereinafter referred to as a second meandered trace for differentiation purposes).

The first conductor strip 161 may be a conductor strip in homocentric squares, an annular conductor strip or a bar conductor strip, and may be provided as capacitance in the LC series resonant circuit formed with the first grounding area 144 (hereinafter referred to as a second 161 and the first grounding area 144 are respectively configured as two electrode plates of equivalent capacitance. It should be understood that there may still be coupling capacitance between the first grounding area 144 and second grounding area 145. However, since the coupling capacitance is numerically significantly smaller than the second capacitance, it is negligible for simplicity of illustration. In this case, by changing the number of first conductor strips 161, the position of the first conductor strip(s) 161 relative to the first grounding area 144, and/or the size and/or shape of the first conductor strip(s) 161, the resonance characteristic of the LC series resonant circuit, for example, the capacitance value of the second capacitance, may be changed to suppress current in the second frequency band in a targeted manner.

Furthermore, the first end 162-1 of the second meandered trace 162 may be electrically connected to the first conductor strip 161, and the second end 162-2 of the second meandered trace 162 may be electrically connected to the second grounding area 145, which may be grounded and coupled with a reflector considered to be a common ground. As such, the second meandered trace 162 may form an inductance in an LC series resonant circuit (hereinafter referred to as a second inductance for differentiation purposes). The inductance value of the second inductance in the LC series resonant circuit 200 can be adjusted by changing the number of second meandered traces 162, the position(s) of the second meandered trace(s) 162 relative to the first conductor strip 161, and/or the size and/or shape of the second meandered trace(s) 162. In this way, the second capacitance and/or second inductance in the LC series resonant circuit can be adjusted in a targeted manner, such that current in the second frequency band is suppressed in a targeted manner.

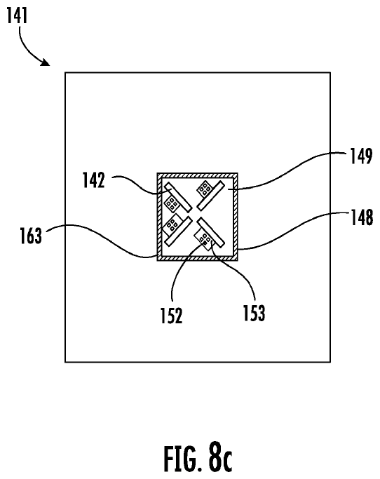

FIGS. 8a and 8b are schematic plan views of the front side and according to a further embodiment of the present disclosure. FIG. 8c is a schematic view of the feed board 141 in FIG. 8a. In the embodiments of FIGS. 8a to 8c, the resonant circuit 200 is configured as a capacitive circuit, for example, a high-pass filter circuit, to allow current within the first frequency band to pass while preventing current within the second frequency band from passing.

Similar to the embodiments of FIGS. 2a to 6c, a first grounding area 144 may be provided on the front surface of the dielectric substrate 143 of the feed board 141, and the grounding conductive area of the first frequency band radiating element 121 is electrically connected to the first grounding area 144. A second grounding area 145 may be provided on the rear surface of the dielectric substrate 143 of the feed board 141, and the second grounding area 145 is coupled to the reflector 113 in a grounding manner. The first grounding area 144 and the second grounding area 145 may form capacitance in the capacitive circuit (hereinafter referred to as third capacitance for differentiation purposes). The second grounding area 145 may be provided with a window 147 at least partially exposing the rear surface of the dielectric substrate 143. The resonance characteristic of the capacitive circuit, for example, the capacitance value of the third capacitance, is capable of being adjusted by changing the number of windows 147, the position of window 147 relative to the first grounding area 144, and/or the size and/or shape of window 147. In this way, current in the second frequency band is capable of being suppressed in a targeted manner.

In the embodiments of FIGS. 8a to 8c, the area of the window 147 may be smaller than the area of the first grounding area 144, and the window 147 may overlap at least a portion of the first grounding area 144. As shown in FIG. 8c, a second projection 149 of the window 147 on the first grounding area 144 on the dielectric substrate 143. In other words, a sub-region 163 that does not overlap the window 147 is present in the first grounding area 144 (represented by right diagonal stripe shading in FIGS. 8a and 8c). In this case, the third capacitance is formed primarily by the sub-region 163 of the first grounding area 144 and the second grounding area 145. The resonance characteristics of the capacitive circuit, for example, the capacitance value of the third capacitance is capable of being adjusted by changing the number, size, and/or shape of the sub-region 163.

The base station antenna 100 according to the various embodiments of the present disclosure is capable of bringing one or more of the following advantages: first, by disposing the resonant circuit 200 on the feed board 141 near the reflector 113, it is capable of effectively improving the decoupling performance, for example, the common-mode signal suppression performance of the radiating elements 121 and 131 in different frequency bands; second, the height h of the first frequency band radiating element 121 in the direction perpendicular to the reflector 113 no longer needs to be shortened to meet decoupling performance requirements, thereby improving the impedance matching and radiation efficiency of the first frequency band radiating element 121; third, by configuring the resonant circuit 200 as a LC parallel resonant circuit (for example, band-stop filter circuit), as a LC series resonant circuit 200 (for example, band-pass filter circuit), or as a capacitive circuit (for example, high-pass filter circuit), it is capable of meeting different decoupling performance, for example, common-mode suppression performance requirements for the base station antenna 100; fourth, the number, position, size and/or shape of the window 147 and/or meandered traces 142 and 162 may be disposed as needed to facilitate targeted adjustment of capacitance and/or inductance in the resonant circuit 200, thereby suppressing current in the second disposed in the grounding path of the first frequency band radiating element 121 and does not take up additional space, which is conducive to the miniaturization of the base station antenna 100.

Although exemplary embodiments of the present disclosure have been described, those skilled in the art should understand that many variations and modifications are possible in the exemplary embodiments without materially departing from the spirit and scope of the present disclosure. Therefore, all variations and changes are included in the protection scope of the present disclosure defined by the claims. The present disclosure is defined by the attached claims, and equivalents of these claims are also included.

1. A base station antenna, comprising:
a reflector;
a first frequency band radiating element located on the front side of the reflector; and
a feed board located on the front side of the reflector, the feed board being configured to feed the first frequency band radiating element,
wherein a resonant circuit in a grounding path of the first frequency band radiating element is formed on the feed board, and the resonant circuit is configured to at least suppress current within a second frequency band different from the first frequency band.

2. The base station antenna according to claim 1, wherein the grounding path extends from the ground connection of the first frequency band radiating element on the feed board to the reflector.

3. (canceled)

4. The base station antenna according to claim 1, wherein the resonant circuit is configured as an LC parallel resonant circuit.

5. The base station antenna according to claim 4, wherein
a first grounding area is provided on the front surface of the dielectric substrate of the feed board, and the grounding conductive area of the first frequency band radiating element is electrically connected to the first grounding area; and
a second grounding area is provided on the rear surface of the dielectric substrate of the feed board, and the second grounding area is coupled to the reflector,
in which, the first grounding area and the second grounding area form a first capacitance in an LC parallel resonant circuit.

6. The base station antenna according to claim 5, wherein the second grounding area is provided with a window that at least partially exposes the rear surface of the dielectric substrate.

7-8. (canceled)

9. The base station antenna according to claim 5, wherein the window overlaps at least a portion of the first grounding area.

10. The base station antenna according to claim 6, wherein a first projection of the first grounding area on the dielectric substrate is located within a second projection of the window on the dielectric substrate.

11. (canceled)

12. The base station antenna according to claim 5, wherein the resonant circuit is provided with a first meandered trace on the front surface of the dielectric substrate, and the first meandered trace forms a first inductance in the LC parallel resonant circuit.

13. The base station antenna according to claim 12, wherein the first end of the first meandered trace is electrically connected to the first grounding area and the second end of the first meandered trace is electrically connected to the second grounding area.

14. The base station antenna according to claim 13, wherein the second end of the first meandered trace is electrically connected to the second grounding area via a first conductive structure that passes through the dielectric substrate.

15-21. (canceled)

22. The base station antenna according to claim 6, wherein the feed board has one or more slots that pass through the first grounding area and dielectric substrate, where a feed stalk of the first frequency band radiating element passes through the front side of the feed board and extends through at least one of the slots to the rear side of the feed board.

23-29. (canceled)

30. The base station antenna according to claim 1, wherein the resonant circuit is configured as an LC series resonant circuit.

31. The base station antenna according to claim 30, wherein a first grounding area is provided on the front surface of the dielectric substrate of the feed board, and the grounding conductive area of the first frequency band radiating element is electrically connected to the first grounding area; and
a second grounding area is provided on the rear surface of the dielectric substrate of the feed board, and the second grounding area is coupled to the reflector in a grounding manner.

32. The base station antenna according to claim 31, wherein the second grounding area is provided with a window that partially exposes the rear surface of the dielectric substrate.

32. The base station antenna according to claim 32, wherein a metal pattern is printed within the window, and the metal pattern comprises a first conductor strip and a second meandered trace.

34. The base station antenna according to claim 33, wherein the first conductor strip is configured as a second capacitance in the LC series resonant circuit formed with the first grounding area.

35. The base station antenna according to claim 33, wherein the second meandered trace forms a second inductance in the LC series resonant circuit.

36. The base station antenna according to claim 33, wherein a first end of the second meandered trace is electrically connected to the first conductor strip, and a second end of the second meandered trace is electrically connected to the second grounding area.

37-46. (canceled)

47. The base station antenna according to claim 1, wherein
the resonant circuit comprises a capacitive circuit,
a first grounding area is provided on the front surface of the dielectric substrate of the feed board, and the grounding conductive area of the first frequency band radiating element is electrically connected to the first grounding area; and
a second grounding area is provided on the rear surface of the dielectric substrate of the feed board, and the second grounding area is coupled to the reflector in a grounding manner,
in which, the first grounding area and the second grounding area form a third capacitance in the capacitive circuit.

48-59. (canceled)

60. The base station antenna according to claim 1, wherein the minimum distance between a radiating arm of the first frequency band radiating element and the reflector in a direction perpendicular to the reflector is in the range of 0.1 to 0.4 wavelength, and the wavelength is the wavelength corresponding to the center frequency of the first frequency band.
